(19) United States
(12) Patent Application Publication
(10) Pub. No.: US 2024/0274773 A1
(43) Pub. Date: Aug. 15, 2024

(54) DISPLAY PANEL MANUFACTURING METHOD

(71) Applicant: SAMSUNG ELECTRONICS CO., LTD., Suwon-si (KR)

(72) Inventors: Changjoon LEE, Suwon-si (KR); Kyungwoon JANG, Suwon-si (KR)

(73) Assignee: SAMSUNG ELECTRONICS CO., LTD., Suwon-si (KR)

(21) Appl. No.: 18/642,363

(22) Filed: Apr. 22, 2024

Related U.S. Application Data
(63) Continuation of application No. PCT/KR2022/014388, filed on Sep. 27, 2022.

(30) Foreign Application Priority Data
Nov. 19, 2021 (KR) 10-2021-0160622
Jan. 10, 2022 (KR) 10-2022-0003461

(51) Int. Cl. H01L 33/62; H01L 23/00; H01L 25/075

(52) U.S. Cl. CPC H01L 33/62; H01L 24/29; H01L 24/32; H01L 24/83; H01L 25/0753; H01L 2224/29028; H01L 2224/32225; H01L 2224/83203; H01L 2924/12041; H01L 2933/0066

(57) ABSTRACT

A display panel manufacturing method includes: putting a first substrate into a liquid; putting a plurality of light emitting diodes into the liquid in which the first substrate is put; performing fluidic self-assembly to attach the plurality of light emitting diodes to the first substrate; transferring the plurality of light emitting diodes attached to the first substrate to a second substrate; and thermally compressing the plurality of light emitting diodes transferred to the second substrate onto the second substrate.

### CROSS-REFERENCE TO RELATED APPLICATIONS

This application is a continuation of International Application No. PCT/KR2022/014388, filed on Sep. 27, 2022, which is based on and claims priority to Korean Patent Application No. 10-2021-0160622, filed on Nov. 19, 2021, and Korean Patent Application No. 10-2022-0003461, filed on Jan. 10, 2022, in the Korean Intellectual Property Office, the disclosures of which are incorporated by reference herein in their entireties.

### BACKGROUND

### 1. Field

The disclosure relates to a manufacturing method of a display panel.

### 2. Description of Related Art

A self-luminous display element displays an image without a color filter and a backlight by using an inorganic light emitting diode emitting a light by itself.

A display panel expresses various colors as it operates in pixel or sub-pixel units. The operation of each pixel or sub-pixel is controlled by a plurality of thin film transistors (TFTs). The plurality of TFTs are provided on one surface, and a plurality of light emitting diodes are electrically connected to the plurality of TFTs.

A plurality of light emitting diodes arranged on a wafer may be transferred to a target substrate by a pick and place method of utilizing an adhesive force of a stamp, or transferred to a target substrate by a laser transfer method.

However, in the pick and place method, as a wavelength distribution included by a wafer is reflected to a target substrate as it is, there is a problem that the wavelength distribution on the wafer is visible on the target substrate. Thus, a process of making locations of the plurality of light emitting diodes transferred to the target substrate is irregular. For a regular process of making locations of the plurality of light emitting diodes transferred to the target substrate, the wavelength distribution must not visible on the target substrate. The current process of the pick and place method has problems of increasing the manufacturing time and increasing the manufacturing cost accordingly.

In the case of the laser transfer method, as an adhesion layer existing between a wafer and light emitting diodes is removed by irradiating a laser beam on the wafer, the light emitting diodes attached on the wafer falls to a target substrate. The laser transfer method has disadvantages in that it is costly to completely remove a wavelength distribution on the wafer, and at the time of laser transfer, it is necessary to go through a complex process for transferring the light emitting diodes to the target substrate without causing damage.

### SUMMARY

Provided is a manufacturing method of a display panel wherein a plurality of light emitting diodes are arranged on a target substrate such that a specific wavelength distribution may not appear on the target substrate.

Provided is a manufacturing method of a display panel which may reduce the manufacturing time, and wherein a plurality of light emitting diodes may contact a target substrate stably.

According to an aspect of the disclosure, a display panel manufacturing method includes: putting a first substrate into a liquid; putting a plurality of light emitting diodes into the liquid in which the first substrate is put; performing fluidic self-assembly to attach the plurality of light emitting diodes to the first substrate; transferring the plurality of light emitting diodes attached to the first substrate to a second substrate; and thermally compressing the plurality of light emitting diodes transferred to the second substrate onto the second substrate.

The display panel manufacturing method may further include, before the putting the first substrate and the plurality of light emitting diodes into the liquid, performing hydrophilic surface processing on a portion of the first substrate and portions of the plurality of light emitting diodes.

The hydrophilic surface processing may include: performing hydrophilic surface processing on one of a first electrode pad or a second electrode pad arranged in pairs on the first substrate; and performing hydrophilic surface processing on one of a first electrode terminal or a second electrode terminal of the plurality of light emitting diodes.

The display panel manufacturing method may further include circulating the liquid such that the plurality of light emitting diodes flow in the liquid and are then inserted into a plurality of guide grooves provided on the first substrate.

The display panel manufacturing method may further include withdrawing the first substrate from the liquid after the fluidic self-assembly is completed.

The transferring the plurality of light emitting diodes may be performed by using a pick and place method.

The transferring the plurality of light emitting diodes arranged on the first substrate to the second substrate may be performed by using a plurality of adhesion heads of a stamper.

The thermally compressing the plurality of light emitting diodes onto the second substrate may include fixing the plurality of light emitting diodes to the second substrate by an adhesion layer provided on one surface of the second substrate.

The display panel manufacturing method may further include, after the fixing the plurality of light emitting diodes to the second substrate by the adhesion layer provided on the one surface of the second substrate, hardening the adhesion layer of the second substrate.

The adhesion layer may be an anisotropic conductive film.

The adhesion layer may be a non-conductive film.

### BRIEF DESCRIPTION OF THE DRAWINGS

The above and other aspects, features, and advantages of certain embodiments of the present disclosure will be more apparent from the following description taken in conjunction with the accompanying drawings, in which:

FIG. 1 is a block diagram illustrating a display device according to one or more embodiments;

FIG. 2 is a plan view illustrating a display panel included in a display device according to one or more embodiments;

FIG. 3 is an enlarged view of the pixels in the A part displayed in FIG. 2 according to one or more embodiments;

FIG. 4 is a flow chart illustrating a manufacturing process of a display panel according to one or more embodiments;

FIG. 5 is a diagram illustrating putting a plurality of light emitting diodes into a liquid stored in a tank according to one or more embodiments;

FIG. 6 is an enlarged view of the B part displayed in FIG. 5 according to one or more embodiments;

FIG. 7 is a diagram illustrating fluidic self-assembly performed to attach a plurality of light emitting diodes to a relay substrate in a liquid stored in a tank according to one or more embodiments;

FIG. 8 is an enlarged view of the C part displayed in FIG. 7 according to one or more embodiments;

FIG. 9 is a diagram illustrating picking a plurality of light emitting diodes arranged on a relay substrate by a stamper according to one or more embodiments;

FIG. 10 is a diagram illustrating transferring a plurality of light emitting diodes to a target substrate by a stamper according to one or more embodiments;

FIG. 11 is an enlarged view of the D part displayed in FIG. 10 according to one or more embodiments;

FIG. 12 is a diagram illustrating placing a plurality of light emitting diodes to a target substrate by a stamper according to one or more embodiments;

FIG. 13 is an enlarged view of the E part displayed in FIG. 12 according to one or more embodiments;

FIG. 14 is a diagram illustrating thermo-compressing a plurality of light emitting diodes to make them contact a substrate stably according to one or more embodiments;

FIG. 15 is an enlarged view of the F part displayed in FIG. 14 according to one or more embodiments; and

FIG. 16 is a diagram illustrating a display panel according to one or more embodiments.

### DETAILED DESCRIPTION

Hereinafter, various embodiments will be described in more detail with reference to the accompanying drawings. The embodiments described in this specification may be modified in various forms. Specific embodiments may be illustrated in the drawings, and explained in detail in the detailed description. However, the specific embodiments disclosed in the accompanying drawings are examples for making the various embodiments understood easily. Accordingly, the technical idea of the disclosure is not limited by the specific embodiments disclosed in the accompanying drawings, and should be interpreted to include all equivalents or alternatives included in the ideas and the technical scopes disclosed herein.

Also, in the disclosure, terms including ordinal numbers such as ‘the first’ and ‘the second’ may be used to describe various components, but these components are not limited by the aforementioned terms. The aforementioned terms are used only for the purpose of distinguishing one component from another component.

In addition, in the disclosure, terms such as “include” or “have” should be construed as designating that there are such characteristics, numbers, steps, operations, elements, components, or a combination thereof described in the specification, but not as excluding in advance the existence or possibility of adding one or more of other characteristics, numbers, steps, operations, elements, components, or a combination thereof. Further, the description in the disclosure that an element is “coupled with/to” or “connected to” another element should be interpreted to mean that the one element may be directly coupled with/to or connected to the another element, but still another element may exist between the elements. In contrast, the description that one element is “directly coupled” or “directly connected” to another element can be interpreted to mean that still another element does not exist between the one element and the another element.

Also, in the disclosure, the expression ‘identical’ not only means that some features perfectly coincide, but also means that the features include a difference in consideration of a machining error range.

Other than the above, in describing the disclosure, in case it is determined that detailed explanation of related known functions or features may unnecessarily confuse the gist of the disclosure, the detailed explanation will be abridged or omitted.

In the disclosure, a display module may include a display panel including inorganic light emitting diodes for displaying images. Here, the display panel may be a flat display panel or a curved display panel, and a plurality of inorganic light emitting diodes having sizes of 100 μm or smaller (e.g., micro LEDs or mini LEDs) are mounted on it, and thus the display panel provides better contrast, response time, and energy efficiency than a liquid crystal display (LCD) that needs a backlight.

Inorganic light emitting diodes applied to the disclosure have better brightness and light emitting efficiency, and a longer lifespan than organic light emitting diodes (OLEDs). Inorganic light emitting diodes may be semiconductor chips that can emit light by themselves in case power is supplied. Micro LEDs which are inorganic light emitting diodes have fast reaction speed, low power consumption, and high luminance. Micro LEDs have higher efficiency in converting electricity into photons than a conventional LCD or OLEDs. That is, micro LEDs have higher “brightness per watt” than a conventional LCD or OLED display. Accordingly, micro LEDs can exert identical brightness with about half the energy compared to LEDs or OLEDs of which sizes exceed 100 μm. Other than this, micro LEDs can implement a high resolution, excellent colors, contrast, and brightness, and thus they can express colors in a wide range correctly, and can implement a clear screen outdoors. Also, micro LEDs are strong against a burn-in phenomenon and generate little heat, and thus a long lifespan without distortion is guaranteed. Micro LEDs may have a flip chip structure wherein an anode electrode and a cathode electrode are formed on the same first surface, and a light emitting surface is formed on a second surface positioned on the opposite side of the first surface wherein the electrodes are formed.

According to one or more embodiments, the front surface of a target substrate, a thin film transistor (TFT) layer wherein a TFT circuit is formed may be arranged, and on the rear surface, a power supply circuit supplying power to the TFT circuit, and a data driving driver, a gate driving driver, and a timing controller controlling each driving driver may be arranged. A plurality of pixels arranged on the TFT layer may be driven by the TFT circuit.

According to one or more embodiments, the TFTs provided to the display module may be low-temperature polycrystalline silicon (LTPS) TFTs, low-temperature polycrystalline oxide (LTPO) TFTs, or oxide TFTs.

According to one or more embodiments, as the target substrate, a glass substrate, a substrate based on a synthetic resin having a flexible material (e.g., polyimide (PI), polyethylene terephthalate (PET), polyethersulfone (PES), polyethylene naphthalate (PEN), polycarbonate (PC), etc.), or a ceramic substrate may be used.

According to one or more embodiments, on the front surface of the target substrate, a TFT layer on which a TFT circuit is formed may be arranged, and a circuit may not be arranged on the rear surface of the target substrate. The TFT layer may be formed integrally on the target substrate, or manufactured in a form of a separate film, and attached on one surface of a glass substrate.

According to one or more embodiments, the front surface of the target substrate may be divided into an active area and an inactive area. The active area may be an area occupied by the TFT layer on the front surface of the target substrate, and the inactive area may be an area excluding the area occupied by the TFT layer on the front surface of the target substrate.

According to one or more embodiments, the edge area of the target substrate may be the outermost area of the glass substrate. Also, the edge area of the target substrate may be the remaining area excluding the area wherein the circuit of the target substrate is formed. Further, the edge area of the target substrate may include a part of the front surface of the target substrate adjacent to the side surface of the target substrate, and a part of the rear surface of the target substrate adjacent to the side surface of the target substrate. The target substrate may be formed as a quadrangle type. For example, the target substrate may be formed as a rectangle or a square. The edge area of the target substrate may include at least one side among the four sides of the glass substrate.

According to one or more embodiments, the TFTs constituting the TFT layer (or the backplane) is not limited to a specific structure or type. According to one or more embodiments, the TFTs cited in the disclosure may be implemented as oxide TFTs and Si TFTs (polysilicon, a-silicon), organic TFTs, graphene TFTs, etc. other than low-temperature polycrystalline silicon (LTPS) TFTs. Also, only P-type (or N-type) metal-oxide-semiconductor field-effect transistors (MOSFETs) may be made in an Si wafer complementary metal-oxide-semiconductor (CMOS) process and applied.

According to one or more embodiments, the target substrate included in the display module is not limited to a TFT substrate. The target substrate may be a substrate wherein there is no TFT layer on which a TFT circuit is formed. In this case, the display module may include a substrate wherein only a wiring is patterned, while a micro integrated computer (IC) is separately mounted.

According to one or more embodiments, the method of driving the pixels of the display module may be an active matrix (AM) driving method or a passive matrix (PM) driving method. The display module may form a pattern of a wiring to which each micro LED is electrically connected according to the AM driving method or the PM driving method.

According to one or more embodiments, the display module may be installed and applied in a single unit on wearable devices, portable devices, handheld devices, and various kinds of electronic products or electronic components which need displays. Also, the display module may be applied as a matrix type to display devices such as monitors for personal computers (PCs), high resolution televisions and signage or digital signage, and electronic displays through a plurality of assembly arrangements.

The display module according to one or more embodiments may include a plurality of inorganic light emitting diodes for displaying images arranged on the target substrate wherein a thin film transistor is formed on one surface. The plurality of inorganic light emitting diodes may be sub-pixels constituting a single pixel. Herein, one ‘light-emitting diode,’ one ‘micro LED,’ and one ‘sub-pixel’ may be interchangeably used as the same meaning.

Hereinafter, the embodiments of the disclosure will be described in detail with reference to the accompanying drawings, such that those having ordinary skill in the art to which the disclosure belongs can easily carry out the disclosure. However, it should be noted that the disclosure may be implemented in various different forms, and is not limited to the embodiments described herein. Also, in the drawings, parts that are not related to explanation were omitted, for explaining the disclosure clearly, and throughout the specification, similar components were designated by similar reference numerals.

Further, while the embodiments of the disclosure will be described in detail with reference to the following accompanying drawings and the content described in the accompanying drawings, it is not intended that the disclosure is restricted or limited by the embodiments.

Hereinafter, a display device according to one or more embodiments of the disclosure will be described with reference to the drawings.

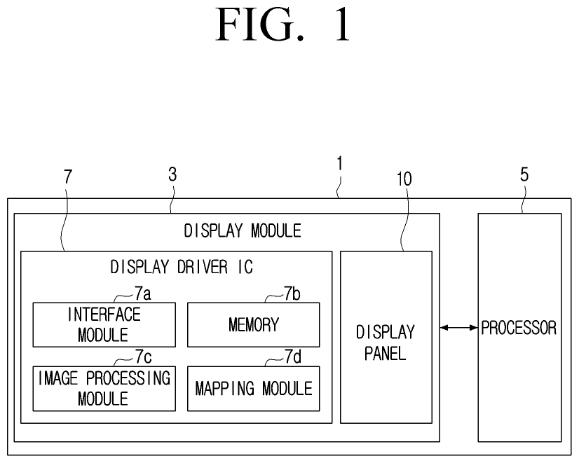

FIG. 1 is a block diagram illustrating a display device according to one or more embodiments.

Referring to FIG. 1, a display device 1 according to one or more embodiments may include a display module 3 and a processor 5.

The display module 3 according to one or more embodiments may display various images. Here, an image includes at least one of a still image or a moving image. The display module 3 may display various images such as a broadcasting content, a multimedia content, etc. Also, the display module 3 may display a user interface and an icon.

The display module 3 may include a display panel 10 and a display driver integrated circuit (IC) 7 for controlling the display panel 10.

The display driver IC 7 may include an interface module 7a, a memory 7b (e.g., a buffer memory), an image processing module 7c, or a mapping module 7d. The display driver IC 7 may receive image data, or image information including an image control signal corresponding to an instruction for controlling the image data from another component of the display device 1 through the interface module 7a. According to one or more embodiments, the image information may be received from the processor 5 (e.g., a main processor (e.g., an application processor)) or a subsidiary processor (e.g., a graphics processing device) operated independently from the function of the main processor.

The display driver IC 7 may store at least some of the received image information in the memory 7b, such as in frame units. The image processing module 7c may perform pre-processing or post-processing (e.g., adjustment of the resolution, the brightness, or the size) of at least some of the image data based on the characteristic of the image data or the characteristic of the display panel 10. The mapping module 7d may generate a voltage value or a current value corresponding to the image data pre-processed or post-processed through the image processing module 7c. According to one or more embodiments, generation of a voltage value or a current value may be performed at least partially based on the attributes of the pixels of the display panel 10 (e.g., the arrangement of the pixels (a red, green, and blue (RGB) stripe or a pentile structure), or the size of each sub-pixel). At least some pixels of the display panel 10 may be operated, for example, at least partially based on the voltage value or the current value, and accordingly, visual information (e.g., a text, an image, or an icon) corresponding to the image data may be displayed through the display panel 10.

The display driver IC 7 may transmit a driving signal (e.g., a driver driving signal, a gate driving signal, etc.) to the display based on the image information received from the processor 5.

The display driver IC 7 may display an image based on an image signal received from the processor 5. According to one or more embodiments, the display driver IC 7 may generate a driving signal of a plurality of sub-pixels based on an image signal received from the processor 5, and display an image by controlling light emission of the plurality of sub-pixels based on the driving signal.

The display module 3 may further include a touch circuit. The touch circuit may include a touch sensor and a touch sensor IC for controlling it. The touch sensor IC may control the touch sensor for detecting a touch input or a hovering input for a designated location of the display panel 10. The touch sensor IC may detect a touch input or a hovering input by measuring change of a signal for a designated location of the display panel 10 (e.g., the voltage, the light amount, the resistance, or the charge amount). The touch sensor IC may provide information about the detected touch input or hovering input (e.g., the location, the area, the pressure, or the time) to the processor 5. According to one or more embodiments, at least a part of the touch circuit (e.g., the touch sensor IC) may be included as a part of the display driver IC 7, or the display panel 10, or as a part of another component (e.g., the subsidiary processor) arranged on the outside of the display module 3.

The processor 5 may be implemented as a digital signal processor (DSP) processing digital image signals, a microprocessor, a graphics processing unit (GPU), an artificial intelligence (AI) processor, a neural processing unit (NPU), and a time controller (TCON). However, embodiments of the disclosure are not limited thereto, and the processor 5 may include one or more of a central processing unit (CPU), a micro controller unit (MCU), a micro processing unit (MPU), a controller, an application processor (AP) or a communication processor (CP), and an ARM processor, or may be defined by the terms. Also, the processor 5 may be implemented as a system on chip (SoC) having a processing algorithm stored therein or large scale integration (LSI), or in forms of an application specific integrated circuit (ASIC) and a field programmable gate array (FPGA).

The processor 5 may control hardware or software components connected to the processor 5 by driving an operating system or an application program, and perform various kinds of data processing and operations. Also, the processor 5 may load instructions or data received from at least one of the other components on a volatile memory and process them, and store various kinds of data in a non-volatile memory.

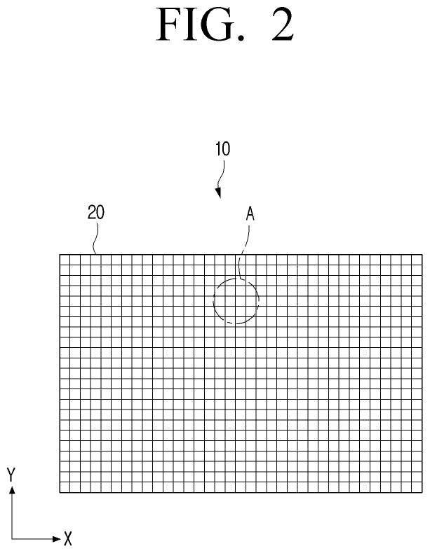

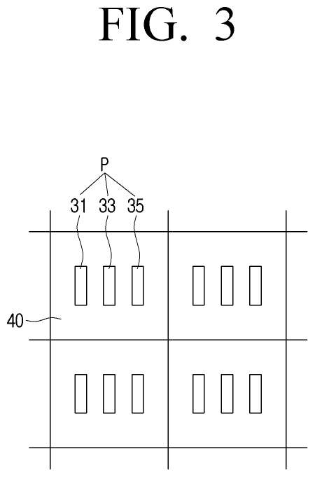

FIG. 2 is a plan view illustrating a display panel included in a display device according to one or more embodiments, and FIG. 3 is an enlarged view of the pixels in the A part displayed in FIG. 2 according to one or more embodiments.

Referring to FIGS. 2 and 3, the display panel 10 may include a plurality of pixels P arranged on the target substrate 20.

The display panel 10 may include a plurality of pixel areas 40 arranged in a matrix form. In each pixel area 40, one pixel P may be arranged, and the one pixel P may include a first sub-pixel 31 emitting a light of a red wavelength band, a second sub-pixel 33 emitting a light of a green wavelength band, and a third sub-pixel 35 emitting a light of a blue wavelength band. According to one or more embodiments, a sub-pixel indicates a light emitting diode.

In the one pixel area 40, in the area not occupied by the first sub-pixel 31, the second sub-pixel 33, and the third sub-pixel 35, a plurality of TFTs for driving the first to third sub-pixels 31, 33, 35 may be arranged.

The first to third sub-pixels 31, 33, 35 may be arranged in a row at specific intervals, but are not limited thereto. According to one or more embodiments, the first to third sub-pixels 31, 33, 35 may be arranged in a form of L, or arranged by a pentile RGBG method. The pentile RGBG method is a method of arranging the number of sub-pixels of red, green, and blue in a ratio of 1:1:2 (RGBG) using the characteristic that a human identifies a blue color less, and identifies a green color best. The pentile RGBG method is effective as a yield rate can be improved and the unit cost can be reduced, and a high resolution can be implemented in a small screen.

The first to third sub-pixels 31, 33, 35 may be micro LEDs or mini LEDs which are inorganic light emitting diodes having sizes of smaller than 100 μm.

The display module 3 may be a touch screen coupled with a touch sensor, a flexible display, a rollable display, and a 3D display. Also, according to one or more embodiments, the display module in the disclosure may be provided as a plurality of display modules, and these modules may be physically connected to implement a large size display (e.g. a large format display (LFD)).

The display panel 10 may include a target substrate that can be implemented in forms such as amorphous silicon (a-Si) TFTs, low temperature polycrystalline silicon (LTPS) TFTs, low temperature polycrystalline oxide (LTPO) TFTs, hybrid oxide and polycrystalline silicon (HOP) TFTs, liquid crystalline polymer (LCP) TFTs, or organic TFTs (OTFTs), etc.

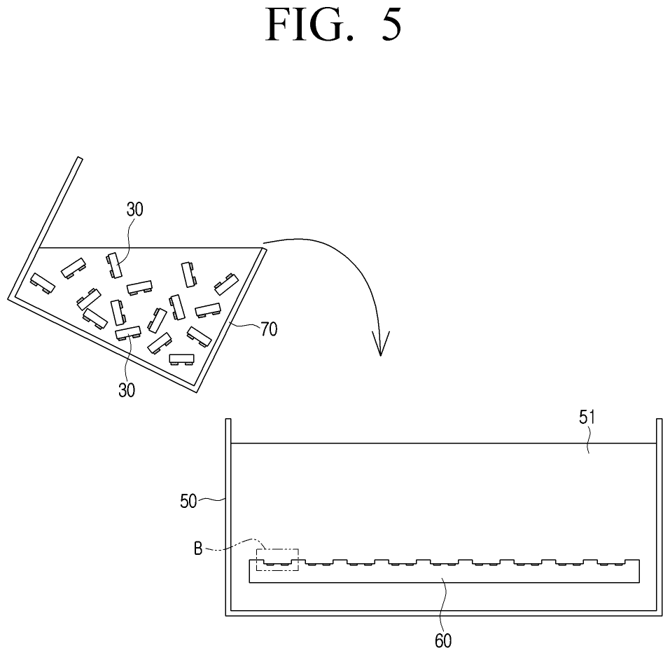

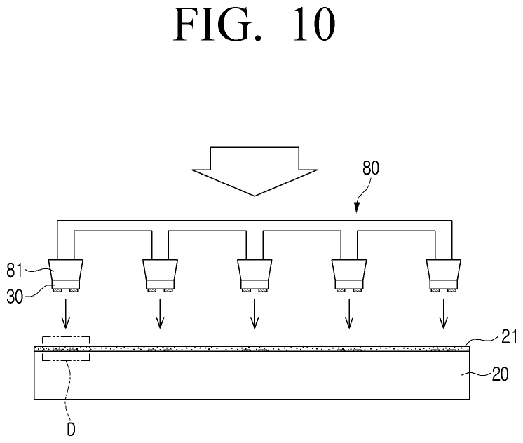

In a manufacturing method of a display panel according to one or more embodiments, a plurality of light emitting diodes may be arranged on a relay substrate 60 (see FIG. 5) at a fast speed while not maintaining the wavelength distribution of a wafer but making the wavelength distribution random through a fluidic self-assembly method. The plurality of light emitting diodes arranged on the relay substrate may be transferred to the target substrate 20 (see FIG. 10) with a stamper 80 (see FIG. 10), and then contact the target substrate 20 steadfastly by a thermo-compression method.

Hereinafter, a manufacturing process of a display panel according one or more embodiments will be described sequentially with reference to the drawings.

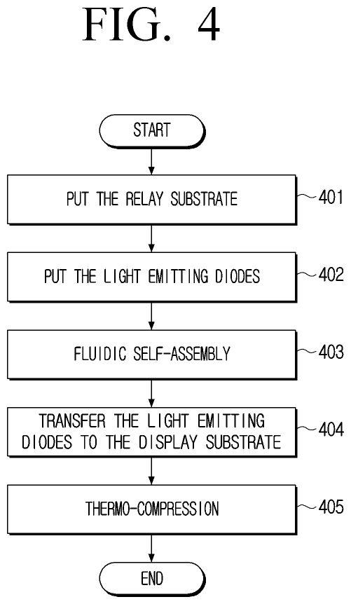

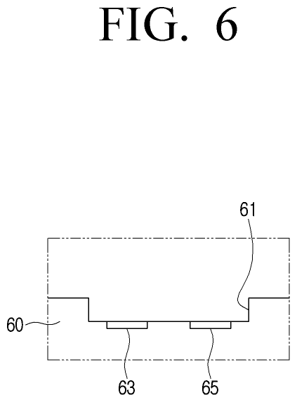

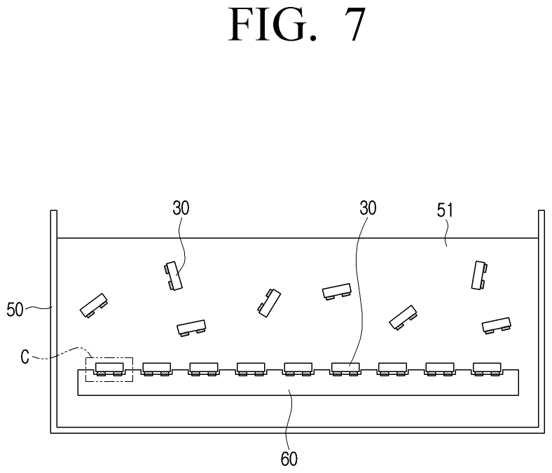

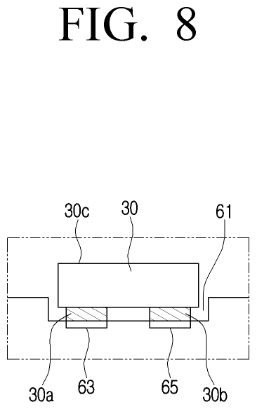

FIG. 4 is a flow chart illustrating a manufacturing process of a display panel according to one or more embodiments. FIG. 5 is a diagram illustrating putting a plurality of light-emitting diodes into a liquid stored in a tank. FIG. 6 is an enlarged view of the B part displayed in FIG. 5 according to one or more embodiments. FIG. 7 is a diagram illustrating fluidic self-assembly performed to attach a plurality of light-emitting diodes to a relay substrate in a liquid stored in a tank according to one or more embodiments. FIG. 8 is an enlarged view of the C part displayed in FIG. 7 according to one or more embodiments.

Referring to FIG. 5 and FIG. 6, on the relay substrate 60, a plurality of guide grooves 61 into which a plurality of light emitting diodes 30 are inserted are provided on one surface. In each guide groove 61, a pair of electrode pads, such as, a first electrode pad 63 and a second electrode 65 may be arranged. The first electrode pad 63 may correspond to a first electrode terminal 30a (see FIG. 8) of the light emitting diodes 30, and the second electrode pad 65 may correspond to a second electrode terminal 30b (see FIG. 8) of the light emitting diodes 30. As the relay substrate 60, a dummy substrate not including a wiring and a circuit may be used.

First, before putting the relay substrate 60 and the plurality of light emitting diodes 30 into the liquid 51 stored in the tank 50, hydrophilic surface processing is performed on each of the relay substrate 60 and the plurality of light emitting diodes 30.

For example, hydrophilic surface processing is performed along the column wherein the plurality of first electrode pads 63 are located on the relay substrate 60. Also, hydrophilic surface processing is performed on one electrode terminal from among the first electrode terminal 30a and the second electrode terminal 30b of each light emitting diode 30, for example, the first electrode terminal 30a. The first electrode terminal 30a may be an anode electrode terminal, and the second electrode terminal 30b may be a cathode electrode terminal. In this case, the first electrode terminal 30a for which hydrophilic processing is performed may be a terminal corresponding to the first electrode pad 63 for which hydrophilic processing was performed on the relay substrate 60.

For the hydrophilic surface processing for reforming the relay substrate 60 and each light emitting diode 30 to be hydrophilic, a chemical processing method, an ultraviolet light irradiation method, an oxygen plasma processing method, etc. may be applied.

Referring to FIG. 5, when hydrophilic processing is performed for the relay substrate 60 and the plurality of light emitting diodes 30, the relay substrate 60 is put into the liquid 51 stored in the tank 50 (401, see FIG. 4). In this case, the relay substrate 60 is arranged such that the plurality of first and second electrode pads 63, 65 (see FIG. 6) are toward the upper surface (i.e. the opening side of the tank 50).

Then, the plurality of light emitting diodes 30 are put into the tank 50 (402, see FIG. 4). The plurality of light emitting diodes 30 may be mixed as it flows in a liquid 51 stored in the container 70.

Referring to FIG. 7, after putting the plurality of light emitting diodes 30 into the liquid 51 in the tank 50, the liquid 51 is circulated. Accordingly, the plurality of light emitting diodes 30 may flow in the liquid 51, and may then be inserted into the guide grooves 61 of the relay substrate 60 due to gravity. Between the first electrode terminal 30a of the light emitting diodes 30 for which hydrophilic processing was performed, and the first electrode pad 63 of the relay substrate 60 for which hydrophilic processing was performed, gravitation gets to operate.

Referring to FIG. 8, the first electrode terminal 30a of the light emitting diodes 30 may stick to the first electrode pad 63 of the relay substrate 60. In this case, the light emitting diodes 30 are guided by the guide grooves 61 of the relay substrate 60, and the second electrode terminal 30b of the light emitting diodes 30 corresponds to the second electrode pad 65 of the relay substrate 60. Accordingly, the plurality of light emitting diodes 30 may be aligned while they are inserted into the plurality of guide grooves 61 of the relay substrate 60.

The plurality of light emitting diodes 30 may be arranged on the relay substrate 60 swiftly by a fluidic self-assembly method (403, see FIG. 4).

An example wherein the plurality of light emitting diodes 30 go through fluidic self-assembly while the relay substrate 60 is put into the liquid 51 in the tank 50 is described above, but embodiment of the disclosure are not limited thereto. According to one or more embodiments, hydrophobic surface processing is performed along the column wherein one electrode (e.g., the first electrode pad 63) from among the plurality of first and second electrode pads 63, 65 is located on the relay substrate 60, and hydrophobic surface processing is performed on the first electrode terminal 30a of each light emitting diode 30. After hydrophobic surface processing is performed, a specific amount of water is sprayed on the upper surface of the relay substrate 60. In this state, while the plurality of light emitting diodes 30 are sprayed on the upper surface of the relay substrate 60, the plurality of light emitting diodes 30 are repeatedly moved in one direction and in a reverse direction thereof by using a device including a plurality of brushes such as a specific broom. In this case, the plurality of light emitting diodes 30 may move as they are pushed by the upper surface of the relay substrate 60 by the device, and may then be inserted into the guide grooves 61 naturally.

When the light emitting diodes 30 are inserted into all guide grooves 61 of the relay substrate 60, the relay substrate 60 is withdrawn from the tank 50.

Such a fluidic self-assembly process, the plurality of light emitting diodes 30 may be randomly arranged on the relay substrate 60. Accordingly, the plurality of light emitting diodes 30 do not maintain the wavelength distribution on the wafer.

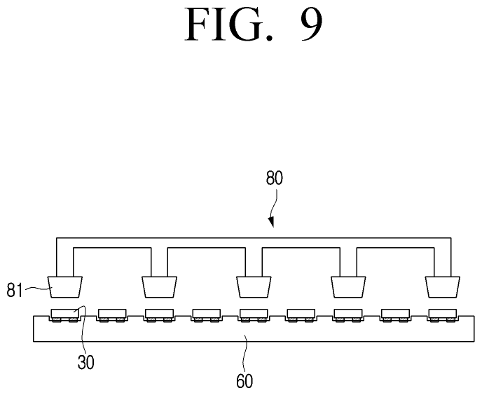

FIG. 9 is a diagram illustrating picking a plurality of light-emitting diodes arranged on a relay substrate by a stamper according to one or more embodiments.

Referring to FIG. 9, a stamper 80 arranged on the upper side of the relay substrate 60 may include a plurality of adhesion heads 81. Each adhesion head 81 picks the plurality of light emitting diodes 30 arranged on the relay substrate 60.

In this case, each light emitting diode 30 is separated from the relay substrate 60 while its light emitting surface 30c (see FIG. 8) is attached to each adhesion head 81. Then, the stamper 80 moves to a predetermined location, e.g., a location to which the plurality of light emitting diodes 30 will be transferred on the target substrate 20.

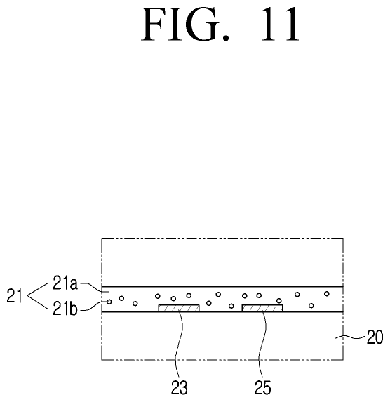

FIG. 10 is a diagram illustrating transferring a plurality of light-emitting diodes to a target substrate by a stamper according to one or more embodiments. FIG. 11 is an enlarged view of the D part displayed in FIG. 10 according to one or more embodiments.

Referring to FIG. 10 and FIG. 11, on one surface of the target substrate 20 on which the plurality of light emitting didoes 30 will be arranged, an adhesion layer 21 may be formed. The adhesion layer 21 may include a resin 21a and a plurality of conductive balls 21b. for example, An epoxy resin, a polyurethane resin, an acrylic resin, etc. may be used as the resin 21a. The plurality of conductive balls 21b have fine diameters (e.g., 3-15 μm), and they may be conductors. Also, the plurality of conductive balls 21b may include polymer particles, and conductive films such as gold (Au), nickel (Ni), lead (Pd), etc. coated on the surfaces of the polymer particles. In this case, as the plurality of conductive balls 21b are distributed inside the resin 21a, the adhesion layer 21 may have conductivity in a compressing direction, and may have a heat insulating property in a vertical direction of the compressing direction. The adhesion layer 21 may be an anisotropic conductive film.

The adhesion layer 21 is not limited to an anisotropic conductive film, and it may be a non-conductive film. In this case, the adhesion layer 21 does not include conductive balls. Accordingly, in the thermo-compression process that will be described below, the first electrode terminal 30a and the second electrode terminal 30b of the light emitting diodes 30 may directly contact the first substrate electrode pad 23 and the second substrate electrode pad 25 of the corresponding target substrate 20.

The stamper 80 descends, and transfers the plurality of light emitting diodes 30 to the target substrate 20 (404, see FIG. 4). In this case, the first electrode terminal 30a of the light emitting diodes 30 may correspond to the first substrate electrode pad 23 of the target substrate 20, and the second electrode terminal 30b of the light emitting diodes 30 may correspond to the second substrate electrode pad 25 of the target substrate 20.

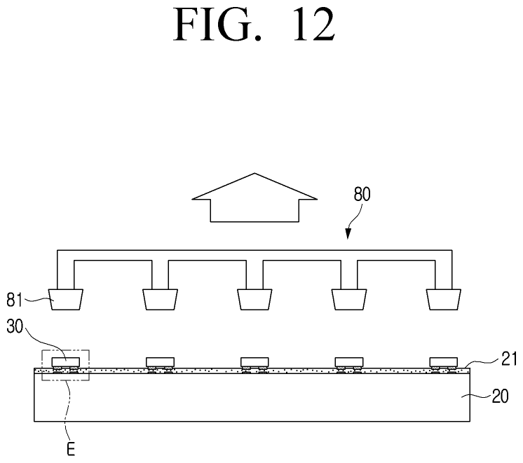

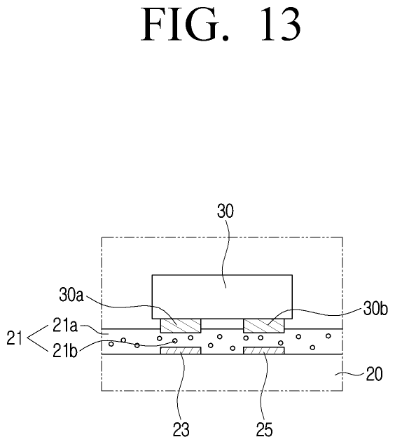

FIG. 12 is a diagram illustrating placing a plurality of light-emitting diodes to a target substrate by a stamper according to one or more embodiments. FIG. 13 is an enlarged view of the E part displayed in FIG. 12 according to one or more embodiments.

Referring to FIG. 12, the stamper 80 ascends after transferring the plurality of light emitting diodes 30 to the target substrate 20. Here, the adhesion force between the plurality of light emitting diodes 30 and the adhesion layer 21 is bigger than the adhesion force between the plurality of light emitting diodes 30 and the adhesion head 81, and thus the plurality of adhesion heads 81 may be separated from the plurality of light emitting diodes 30.

Referring to FIG. 13, in the plurality of light emitting diodes 30 attached on the adhesion layer 21, the first and second electrode terminals 30a, 30b may be distanced from the first and second substrate electrode pads 23, 25 of the corresponding target substrate by a specific interval.

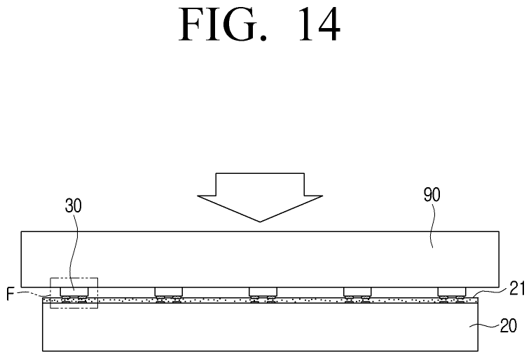

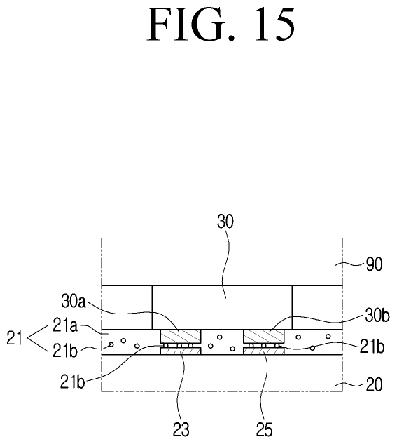

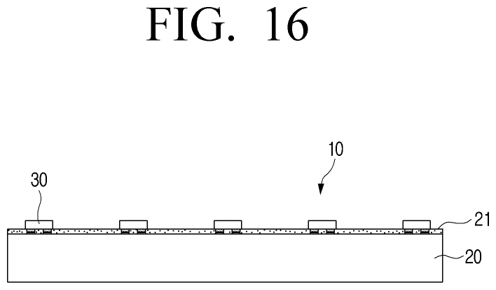

FIG. 14 is a diagram illustrating thermo-compressing a plurality of light-emitting diodes to make them contact a substrate stably according to one or more embodiments. FIG. 15 is an enlarged view of the F part displayed in FIG. 14. FIG. 16 is a diagram illustrating a display panel according to one or more embodiments.

Referring to FIG. 14, the plurality of light emitting diodes 30 are pressurized by a pressurizing member 90, and the plurality of light emitting diodes 30 are thermo-compressed to the target substrate 20 (405, see FIG. 4).

On each of the inner side of the pressurizing member 90 and the inner side of a stage on which the target substrate 20 is seated, a heater (e.g., a sheath heater) may be arranged. In this case, the pressurizing member 90 and the stage may consist of a material having high heat transmission efficiency.

Referring to FIG. 15, the adhesion layer 21 may be heated by heat transferred from the pressurizing member 90 and the stage. Here, the first and second electrode terminals 30a, 30b of each light emitting diode 30 pressurized by the pressurizing member 90 may adhere to the first and second substrate electrode pads 23, 25 of the corresponding target substrate 20.

In this case, in the space between the first electrode terminal 30a and the first substrate electrode pad 23, and in the space between the second electrode terminal 30b and the second substrate electrode pad 25, the plurality of conductive balls 21b get to be located. Accordingly, the first electrode terminal 30a and the first substrate electrode pad 23 are electrically connected by the plurality of conductive balls 21b, and the second electrode terminal 30b and the second substrate electrode pad 25 are electrically connected by the plurality of conductive balls 21b.

Referring to FIG. 16, the display panel 10 that was manufactured by going through a thermo-compression process may go through hardening processing. Accordingly, the plurality of light emitting diodes 30 arranged on the target substrate 20 may be physically fixed to the target substrate steadfastly as the resin 21a of the adhesion layer 21 is hardened.

As described above, in the manufacturing method of a display panel according to one or more embodiments, the plurality of light emitting diodes 30 may be arranged to be randomly distributed on the relay substrate 60 by a fluidic self-assembly method. Accordingly, when the plurality of light emitting diodes 30 are transferred from the relay substrate 60 to the target substrate 20, the wavelength distribution of the wafer on the target substrate 20 is not maintained, but may be arranged randomly. Accordingly, in the display panel 10 including the target substrate 20 in the disclosure, a specific wavelength distribution (e.g. a wavelength distribution on the wafer) is not visible.

Also, the plurality of light emitting diodes 30 transferred from the relay substrate 60 to the target substrate 20 may be physically fixed to the target substrate 20 steadfastly as they go through a thermo-compression process. In this case, each of the first and second electrode terminals 30a, 30b of the plurality of light emitting diodes 30 may be electrically connected to the first and second substrate electrode pads 23, 25 of the corresponding target substrate 20.

While specific example embodiments of the disclosure have been shown and described, the disclosure is not limited to the aforementioned specific embodiments, and it is apparent that various modifications may be made by those having ordinary skill in the technical field to which the disclosure belongs, without departing from the gist of the disclosure as claimed by the appended claims. Further, it is intended that such modifications are not to be interpreted independently from the technical idea or prospect of the disclosure.

What is claimed is:

1. A display panel manufacturing method comprising:
putting a first substrate into a liquid;
putting a plurality of light emitting diodes into the liquid in which the first substrate is put;
performing fluidic self-assembly to attach the plurality of light emitting diodes to the first substrate;
transferring the plurality of light emitting diodes attached to the first substrate to a second substrate; and
thermally compressing the plurality of light emitting diodes transferred to the second substrate onto the second substrate.

2. The display panel manufacturing method of claim 1, further comprising:
before the putting the first substrate and the plurality of light emitting diodes into the liquid, performing hydrophilic surface processing on a portion of the first substrate and portions of the plurality of light emitting diodes.

3. The display panel manufacturing method of claim 2, wherein the hydrophilic surface processing comprises:
performing hydrophilic surface processing on one of a first electrode pad or a second electrode pad arranged in pairs on the first substrate; and
performing hydrophilic surface processing on one of a first electrode terminal or a second electrode terminal of the plurality of light emitting diodes.

4. The display panel manufacturing method of claim 1, further comprising:
circulating the liquid such that the plurality of light emitting diodes flow in the liquid and are then inserted into a plurality of guide grooves provided on the first substrate.

5. The display panel manufacturing method of claim 1, further comprising:
withdrawing the first substrate from the liquid after the fluidic self-assembly is completed.

6. The display panel manufacturing method of claim 1, wherein the transferring the plurality of light emitting diodes is performed by using a pick and place method.

7. The display panel manufacturing method of claim 6, wherein the transferring the plurality of light emitting diodes arranged on the first substrate to the second substrate is performed by using a plurality of adhesion heads of a stamper.

8. The display panel manufacturing method of claim 1, wherein the thermally compressing the plurality of light emitting diodes onto the second substrate comprises fixing the plurality of light emitting diodes to the second substrate by an adhesion layer provided on one surface of the second substrate.

9. The display panel manufacturing method of claim 8, further comprising:
after the fixing the plurality of light emitting diodes to the second substrate by the adhesion layer provided on the one surface of the second substrate, hardening the adhesion layer of the second substrate.

10. The display panel manufacturing method of claim 8, wherein the adhesion layer is an anisotropic conductive film.

11. The display panel manufacturing method of claim 8, wherein the adhesion layer is a non-conductive film.
